(19) United States
(12) Patent Application Publication
(10) Pub. No.: US 2026/0182362 A1
(43) Pub. Date: Jun. 25, 2026

(54) SEMICONDUCTOR DEVICE AND FABRICATION METHOD THEREOF

(71) Applicant: Taiwan Semiconductor Manufacturing Company, Ltd., Hsinchu (TW)

(72) Inventor: Jhon Jhy Liaw, Hsinchu County (TW)

(73) Assignee: Taiwan Semiconductor Manufacturing Company, Ltd., Hsinchu (TW)

(21) Appl. No.: 19/000,705

(22) Filed: Dec. 24, 2024

(51) Int. Cl. H01L 23/522; H01L 23/528; H10D 1/00; H10D 1/68; H10D 30/00; H10D 30/01; H10D 30/43; H10D 62/10; H10D 84/80

(52) U.S. Cl. CPC H10W 20/496; H10D 1/043; H10D 1/696; H10D 1/716; H10D 84/813; H10W 20/42; H10W 20/435; H10D 30/014; H10D 30/0191; H10D 30/43; H10D 30/502; H10D 62/121

(57) ABSTRACT

The present disclosure relates to a semiconductor device including a semiconductor structure, a front side circuit structure and a backside circuit structure. The semiconductor structure includes a semiconductor transistor. The front side circuit structure is disposed over and electrically connected to a gate structure of the semiconductor transistor. The backside circuit structure is disposed on a backside of the semiconductor structure. The backside circuit structure includes a MIM capacitor and a power line electrically connected to the MIM capacitor. The MIM capacitor includes a first electrode, a second electrode and a dielectric layer disposed between the first electrode and the second electrode.

### BACKGROUND

Capacitors play an increasingly vital role in integrated circuits (ICs), especially as the trend toward device miniaturization continues to advance. As the size of components within ICs decreases, capacitors must also be scaled down accordingly. However, maintaining stable performance during this miniaturization process becomes significantly more challenging. Shrinking dimensions may lead to increased parasitic effects, which may negatively impact the overall circuit performance. Furthermore, manufacturing technologies should be precisely controlled to ensure these miniature capacitors operate reliably within high-density circuits.

As miniaturization progresses, the selection of materials and fabrication techniques becomes more complex. Despite the reduced size, capacitors are still required to maintain high capacitance and low loss, presenting significant challenges for modern IC design.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1C are various schematic diagrams of a semiconductor device according to some embodiments of the present disclosure.

FIG. 2A to FIG. 2G are schematic cross-sectional views of various stages of the fabrication method of the Metal-Insulator-Metal (MIM) capacitor in the backside circuit structure of some embodiments of the present disclosure.

FIG. 3 is a schematic cross-sectional view of a semiconductor device according to some embodiments of the present disclosure.

FIG. 4 is a schematic cross-sectional view of a semiconductor device according to some embodiments of the present disclosure.

FIG. 5 is a schematic cross-sectional view of a semiconductor device according to some embodiments of the present disclosure.

FIG. 6A and FIG. 6B are various schematic diagrams of a semiconductor device according to some embodiments of the present disclosure.

FIG. 7A to FIG. 7I are schematic cross-sectional views of various stages of the fabrication method of the MIM capacitor in the backside circuit structure of some embodiments of the present disclosure.

FIG. 8 is a schematic cross-sectional view of a semiconductor device according to some embodiments of the present disclosure.

FIG. 9A to FIG. 9X are various schematic diagrams of various stages of the fabrication method of transistors in a semiconductor structure of some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some semiconductor devices, a semiconductor structure includes multiple transistors, such as, but not limited to, a planar field-effect transistor (planar FET), FinFET, Gate-All-Around FET (GAA FET), nanosheet/nanowire FET, and vertical FET. A front-side circuit structure is disposed over the front side of the semiconductor structure, while a backside circuit structure is disposed on the backside of the semiconductor structure. The semiconductor structure is sandwiched between the front-side and backside circuit structures. In certain embodiments, the front-side circuit structure contains intricate logic circuits, with signal lines used to transmit the signals that need to be processed during chip operations. The backside circuit structure primarily includes power rails, such as a power mesh formed of power lines, configured to provide power and ground connections. To accommodate the transmission of various signals, the front-side circuit structure typically includes multiple conductive and insulating layers, where different conductive layers are electrically connected through conductive vias. Since the backside circuit structure is relatively simpler, the number of conductive layers is generally fewer than those in the front side circuit structure. For example, the number of interconnect layers in the front side circuit structure exceeds 10 layers, while the number of interconnect layers in the backside circuit structure is fewer than or equal to 10 layers (for example, 4 layers to 10 layers).

With the advancement of semiconductor technology, the integration density of semiconductor devices continues to increase, making it more difficult to integrate capacitors with sufficient capacitance into the device. In the embodiments of this disclosure, by integrating the capacitor into the backside circuit structure, the layout space may be utilized more efficiently, and the complex circuits in the front side circuit structure are less likely to affect the performance of the capacitor. On the other hand, in the front side circuit structure, to reduce resistance value, it is generally preferred that the height of the conductive vias connecting different conductive layers be small. However, if a vertical capacitor is to be constructed, the front side circuit structure will require the stacking of more insulating and conductive layers in the vertical direction. This would necessitate additional stacked conductive vias to transmit signals in the front-side circuit structure, which increases resistance and negatively impacts signal transmission. By integrating the capacitor into the backside circuit structure, the disclosed embodiments can avoid these issues.

In some embodiments of this disclosure, the capacitor includes a Metal-Insulator-Metal (MIM) capacitor and may be used for various functions, such as a decoupling capacitor, a high-frequency noise filtering capacitor in mixed-signal applications, an oscillator, a phase shift network, a bypass filter, a coupling capacitor for RF applications, or other functions. In some embodiments, the MIM capacitor may be a planar capacitor, a capacitor with finger-shaped electrodes (where both electrodes are formed on the same plane in a finger-like interdigitated arrangement), or a vertical capacitor. In the vertical capacitor, the electrodes are filled into trenches of an insulating structure, and the cross-section of the electrodes within the trenches includes annular structures.

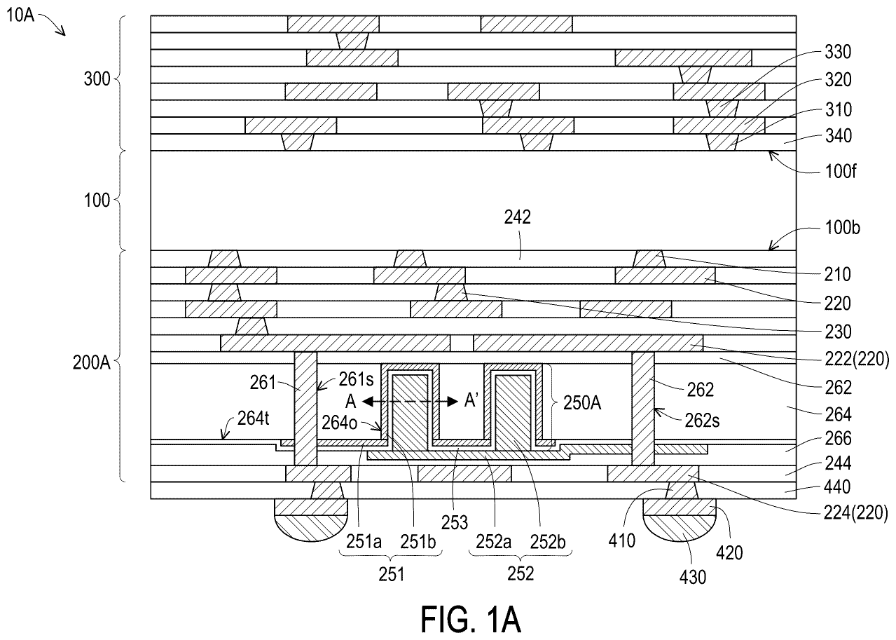

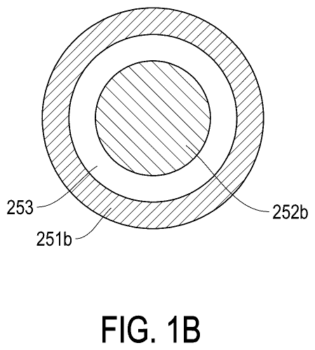

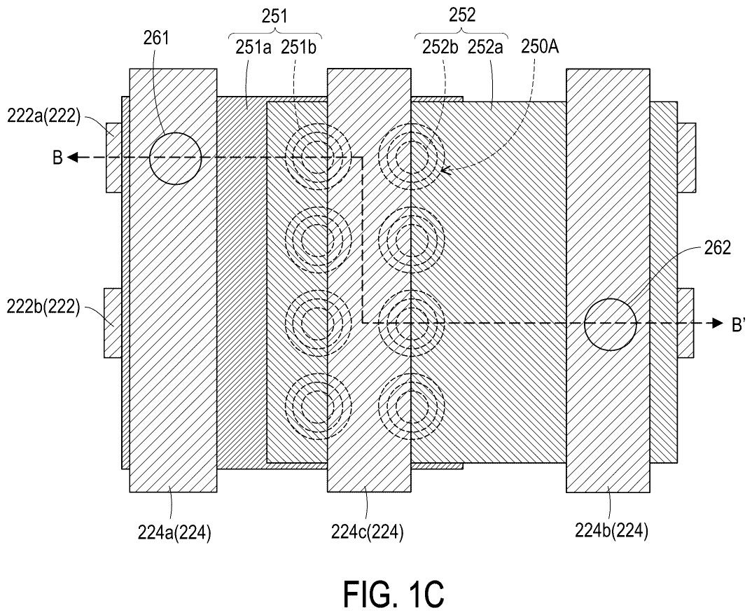

FIG. 1A to FIG. 1C are various schematic diagrams of a semiconductor device 10A according to some embodiments of the present disclosure. FIG. 1C is a perspective bottom view of the semiconductor device 10A. FIG. 1A is a schematic cross-sectional view along line B-B′ of FIG. 1C. FIG. 1B is a schematic cross-sectional view along line A-A′ of FIG. 1A. Referring to FIG. 1A to FIG. 1C, the semiconductor device 10A includes a semiconductor structure 100, a front side circuit structure 300 disposed on a front side 100f of the semiconductor structure 100, and a backside circuit structure 200A disposed on a backside 100b of the semiconductor structure 100.

The semiconductor structure 100 includes, for example, a semiconductor substrate and multiple active components (such as transistors) formed on or within the semiconductor substrate. The semiconductor structure 100 may include materials such as silicon, germanium, silicon carbide, gallium nitride, gallium arsenide, or other types of semiconductor materials. The transistors (not shown) may be, for instance, planar FET, FinFET, GAA FET, nanosheet/nanowire FET, and/or vertical FET. In certain embodiments, the transistors are arranged along the front side 100f of the semiconductor structure 100 opposite to the backside circuit structure 200A, and gate structures of the transistor are electrically connected to the front side circuit structure 300. The structure of the transistor will be further illustrated in subsequent embodiments.

The front side circuit structure 300 includes multiple stacked insulating layers 340. Conductive pattern layers 320 and vias 330 are embedded in the insulating layers 340. The different conductive pattern layers 320 are electrically connected through the vias 330. In some embodiments, one of the conductive pattern layers 320 (for example, the bottom-most conductive pattern layer 320) is electrically connected to the semiconductor structure 100 through contact vias 310. For instance, the contact vias 310 may electrically connect to the gate structure or the source/drain structure of the transistor in the semiconductor structure 100. In certain embodiments, the front side circuit structure 300 may be referred to as an interconnect structure, and the conductive pattern layers 320 may be referred to as interconnect layers. In some embodiments, the contact vias 310, the conductive pattern layers 320 and the vias 330 within the front side circuit structure 300, together with the components (such as transistors) in the semiconductor structure 100, form a logic circuit.

The backside circuit structure 200A includes a MIM capacitor 250A. In some embodiments, the backside circuit structure 200A includes multiple stacked insulating layers 242. Conductive pattern layers 220 and vias 230 are embedded in the insulating layers 242. The different conductive pattern layers 220 are electrically connected through the vias 230. In some embodiments, one of the conductive pattern layers 220 (for example, the conductive pattern layer 220 closest to the semiconductor structure 100) is electrically connected to the semiconductor structure 100 through backside contacts 210. In some embodiments, the conductive pattern layers 220 include Ti, TiN, TaN, Pt, Mo (molybdenum), W (tungsten), Co (cobalt), Ru (ruthenium), Ir (iridium), Rh (rhodium), Cu, or combinations thereof.

The bottom insulating layer 262, the insulating structure 264, and the capping layer 266 are stacked on top of the insulating layers 242. The MIM capacitor 250A is located within the bottom insulating layer 262, the insulating structure 264, and the capping layer 266. For example, the bottom insulating layer 262 is formed over one of the conductive pattern layers 220 (marked as conductive pattern layer 222 in FIG. 1A), while the insulating structure 264 and the capping layer 266 are sequentially stacked on top of the bottom insulating layer 262.

The MIM capacitor 250A includes a first electrode 251, a second electrode 252, and a dielectric layer 253. In some embodiments, the MIM capacitor 250A has a capacitance greater than 100 fF/μm², preferably within the range of 100 fF/μm² to 3,000 fF/μm².

The first electrode 251 is located within the trenches 264o of the insulating structure 264, covering the bottom surfaces and sidewalls of the trenches 264o. The first electrode 251 includes an extending portion 251a and multiple liner portions 251b. The extending portion 251a is located on the top surface 264t of the insulating structure 264, while the liner portions 251b are situated within the trenches 264o and connected to the extending portion 251a. The liner portions 251b cover the bottom surfaces and sidewalls of the trenches 264o. The dielectric layer 253 is disposed over the first electrode 251. The second electrode 252 is disposed over both the first electrode 251 and the dielectric layer 253. The second electrode 252 includes several plug portions 252b and a plate portion 252a. The plug portions 252b are located within the trenches 264o, while the plate portion 252a is positioned above the top surface 264t of the insulating structure 264 and connected to the plug portions 252b. The dielectric layer 253 is placed between the first electrode 251 and the second electrode 252.

In this embodiment, the MIM capacitor 250A is a vertical capacitor, where the plug portions 252b and the liner portions 251b both extend in the vertical direction. This structure allows the MIM capacitor 250A to achieve the benefits of a small footprint and a high capacitance value. In some embodiments, the MIM capacitor 250A includes an array of plug portions 252b, and the number of plug portions 252b in a single MIM capacitor 250A may be adjusted based on specific requirements.

In some embodiments, the first electrode 251 and the second electrode 252 may each be composed of a single conductive layer or multiple conductive layers. For example, the materials for the first electrode 251 and the second electrode 252 may include Ti, TiN, TaN, Co, Ru, Pt, W, Al, Cu, or a combination of these, or other suitable conductive materials. In some embodiments, the thickness of the first electrode 251 along the sidewalls of the trenches 264o (specifically, the horizontal thickness of the liner portions 251b along the sidewalls of the trenches 264o) is less than 30 nm, for example, ranging from 1 nm to 30 nm.

In some embodiments, the bottom insulating layer 262, the insulating structure 264, the capping layer 266, and the dielectric layer 253 may each have a single-layer or multi-layer structure. For example, the materials used for the bottom insulating layer 262, the insulating structure 264, the capping layer 266, and the dielectric layer 253 may include SiO₂, Si₃N₄, carbon-containing oxides (such as SiOC), nitrogen-containing oxides (such as SiON), carbon and nitrogen-containing oxides (such as SiOCN), metal oxides (such as HfO₂, Ta₂O₅, TiO₂, ZrO₂, Al₂O₃, Y₂O₃, or multi-metal oxides), or a combination of these, as well as other suitable insulating materials. In some embodiments, the thickness of the dielectric layer 253 ranges from 5 angstroms to 60 angstroms, for example, from 10 angstroms to 50 angstroms. In some embodiments the dielectric layer 253 includes high-k dielectric materials. As such, the dielectric layer 253 may have a k value greater than about 4.0 or even greater than about 10.0.

In this embodiment, the liner portions 251b of the first electrode 251 within the trenches 264o form an annular structure that surrounds the plug portions 252b of the second electrode 252, as shown in FIG. 1B. Within the trenches 264o, the dielectric layer 253 is laterally positioned between the liner portions 251b of the first electrode 251 and the plug portions 252b of the second electrode 252.

In some embodiments, one or more of the conductive pattern layer(s) 220 and insulating layer(s) 244 are disposed above the capping layer 266, with the conductive pattern layers 220 closest to the capping layer 266 marked as the conductive pattern layer 224 in FIG. 1A. A first conductive via 261 and a second conductive via 262 are positioned in and penetrate through the bottom insulating layer 262, the insulating structure 264, the dielectric layer 253, and the capping layer 266. These vias connect the conductive pattern layer located above the MIM capacitor 250A (such as the conductive pattern layer 224) to the conductive pattern layer located below the MIM capacitor 250A (such as the conductive pattern layer 222).

In some embodiments, the first conductive via 261 passes through the first electrode 251, and the first electrode 251 is electrically connected to a sidewall 261s of the first conductive via 261. On the other hand, the second conductive via 262 passes through the second electrode 252, and the second electrode 252 is electrically connected to a sidewall 262s of the second conductive via 262. In other embodiments, the second conductive via 262 does not pass through the second electrode 252 and terminates at the second electrode 252.

In certain embodiments, the back side circuit structure 200A may be referred to as an interconnect structure, and the conductive pattern layers 220 may be referred to as interconnect layers. In some embodiments, the insulating layers 242, the bottom insulating layer 262, the insulating structure 264, the capping layer 266, and the insulating layer 244 may collectively be referred to as inter-metal or inter-level dielectrics (IMD).

In some embodiments, one or more of the conductive pattern layers 320 include power rails, which may form a power mesh electrically connected to the MIM capacitor 250A. For example, as shown in FIG. 1C, the conductive pattern layer 222 includes a first power line 222a and a second power line 222b. The conductive pattern layer 224 includes a third power line 224a and a fourth power line 224b. The first power line 222a is electrically connected to the third power line 224a through the first conductive via 261, while the second power line 222b is electrically connected to the fourth power line 224b through the second conductive via 263. In this embodiment, a first power mesh includes the first power line 222a and the third power line 224a, and a second power mesh includes the second power line 222b and the fourth power line 224b. In some embodiments, the first power line 222a and the third power line 224a are electrically connected to one of the power supply voltages, either the first power supply voltage VSS or the second power supply voltage VDD, while the second power line 222b and the fourth power line 224b are connected to the other power supply voltage. In other words, one of the first power mesh and the second power mesh is electrically connected to the first power supply voltage VSS, while the other is connected to the second power supply voltage VDD.

In some embodiments, the conductive pattern layer 224 in the back side circuit structure 200A optionally includes a signal line 224c that overlaps the MIM capacitor 250A.

The protective layer 440 is disposed over the outermost conductive pattern layer 220. In some embodiments, the number of conductive pattern layers 220 between the MIM capacitor 250A and the semiconductor structure 100, as well as the number of conductive pattern layers 220 between the MIM capacitor 250A and the protective layer 440, can be adjusted based on actual needs. In other words, this disclosure does not limit which two conductive pattern layers 220 the MIM capacitor 250A is located between within the backside circuit structure 200A. The closer the MIM capacitor 250A is to the outermost conductive pattern layer 220, the fewer conductive pattern layers 220 are affected by the shape of the MIM capacitor 250A. In this embodiment, the MIM capacitor 250A is located between the two outermost conductive pattern layers 220, specifically the conductive pattern layers 222 and 224. In some embodiments, the protective layer 440 includes polyimide or other suitable materials.

Bonding pads 420 are disposed over the protective layer 440 and are electrically connected to the outermost conductive pattern layer 220 through contacts 410. In some embodiments, the bonding pads 420 include Al, Cu, Ni, or other suitable materials. In some embodiments, the bonding pads 420 may be or include under bump metallurgy or under ball metallurgy. In some embodiments, additional redistribution structure may be disposed between the bonding pads 420 and the outermost conductive pattern layer 220, wherein the redistribution structure includes one or more redistribution layer(s).

A plurality of conductive terminals 430 are positioned over the backside circuit structure 200A. Specifically, the conductive terminals 430 are disposed on the bonding pads 420. The MIM capacitor 250A is located between the conductive terminals 430 and the semiconductor structure 100. In some embodiments, the conductive terminals 430 may consist of or include solder balls, ball grid array (BGA) connectors, metal pillars, controlled collapse chip connection (C4) bumps, micro bumps, electroless nickel-electroless palladium-immersion gold (ENEPIG) formed bumps, lead free bumps, lead free balls, or similar structures.

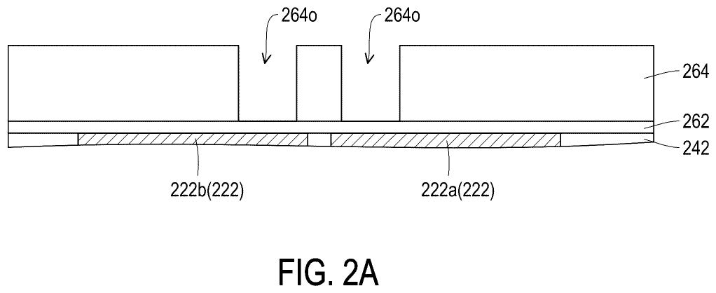

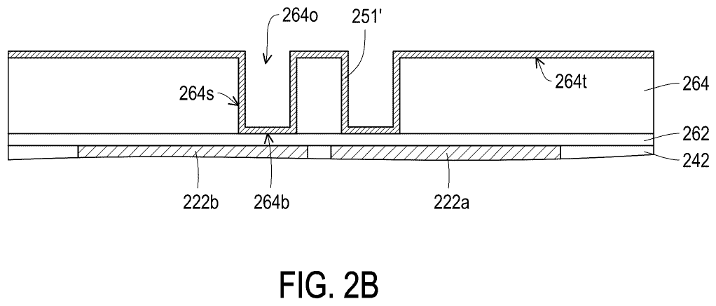

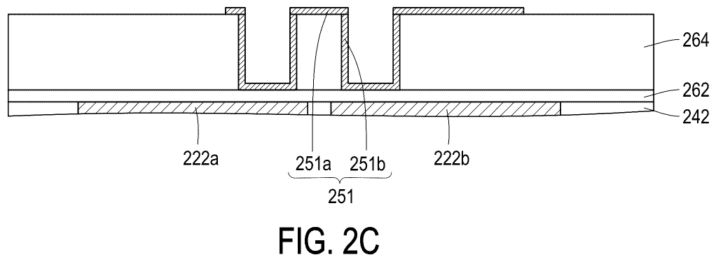

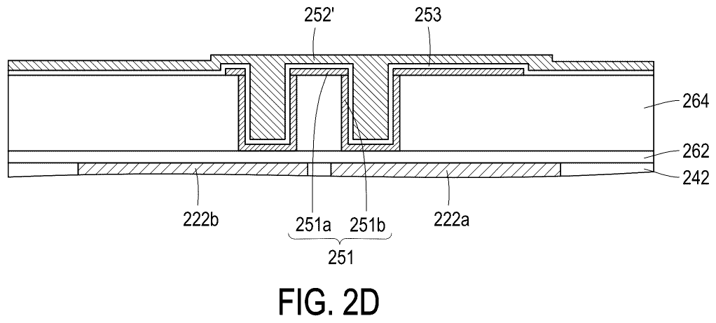

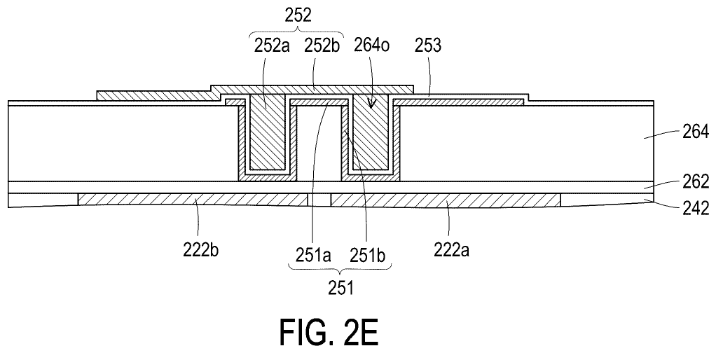

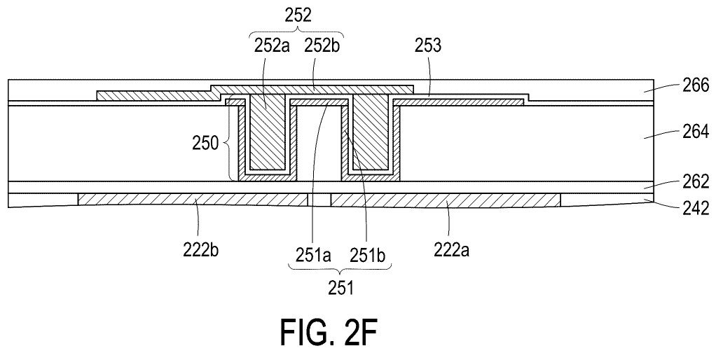

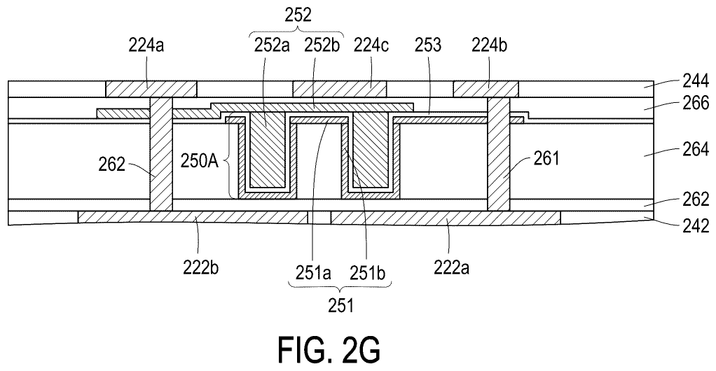

FIGS. 2A to 2G present schematic cross-sectional views depicting various stages in the fabrication method of the MIM capacitor within the backside circuit structure of certain embodiments of the present disclosure. Specifically, these figures illustrate the different stages involved in forming the MIM capacitor 250A within the backside circuit structure 200A, as shown in FIG. 1A. The fabrication method of the backside circuit structure 200A encompasses the various steps for forming the MIM capacitor 250A, as depicted in FIGS. 2A to 2G.

As illustrated in FIG. 2A, the bottom insulating layer 262 and the insulating structure 264 are sequentially formed over the insulating layers 242. In some embodiments, the conductive pattern layer 222, which includes a first power line 222a and a second power line 222b, is embedded within the insulating layer 242. In certain implementations, a front side circuit structure 300 is first formed on the front side 100f of the semiconductor structure 100, followed by the formation of the conductive pattern layers 220 and vias 230 located beneath the conductive pattern layer 222 on the backside 100b of the semiconductor structure 100, as shown in FIGS. 1A and 2A. Subsequently, the conductive pattern layer 222 is formed, and the bottom insulating layer 262 and the insulating structure 264 are formed over the conductive pattern layer 222.

The trenches 264o in the insulating structure 264 may be formed using lithography processes, etch processes, or other suitable methods. In certain embodiments, the depth of the trenches 264o ranges from 100 nm to 10,000 nm.

Referring to FIG. 2B, a first conductive layer 251′ is formed over the top surface 264t of the insulating structure 264, covering both the bottom surfaces 264b and the sidewalls 264s of the trenches 264o. In some embodiments, the bottom insulating layer 262 may reduce the likelihood of the first conductive layer 251′ contacting the first power line 222a and the second power line 222b, thereby lowering the risk of short circuits.

Referring to FIG. 2C, the first conductive layer 251′ is patterned to form the first electrode 251, which includes the extending portion 251a and the liner portions 251b. In some embodiments, the methods for patterning the first conductive layer 251′ include wet etch, dry etch, or a combination of both.

Referring to FIG. 2D, a dielectric layer 253 is formed on the first electrode 251. A second conductive layer 252′ is formed on the dielectric layer 253. The second conductive layer 252′ overlaps and separated from the first electrode 251.

Referring to FIG. 2E, the second conductive layer 252′ is patterned to form the second electrode 252, which includes several plug portions 252b and a plate portion 252a. The plug portions 252b are located in the trenches 264o, and a part of the dielectric layer 253 is disposed between the first electrode 251 and the second electrode 252. In some embodiments, the methods for patterning the second conductive layer 252′ include wet etch, dry etch, or a combination of both.

Referring to FIG. 2F, the capping layer 266 is formed over the second electrode 252.

Referring to FIG. 2G, the first conductive via 261 and the second conductive via 262 are formed. For example, an opening is formed through the bottom insulating layer 262, the insulating structure 264, the first electrode 251, the dielectric layer 253, and the capping layer 266. Then, conductive material is filled into this opening to form the first conductive via 261. Similarly, another opening is formed through the bottom insulating layer 262, the insulating structure 264, the second electrode 252, the dielectric layer 253, and the capping layer 266, followed by filling conductive material into this opening to form the second conductive via 262. The first conductive via 261 and the second conductive via 262 are respectively located above the first power line 222a and the second power line 222b.

Then, the insulating layer 244 is formed over the capping layer 266. The third power line 224a and the fourth power line 224b are embedded within the insulating layer 244 and are positioned directly above the first conductive via 261 and the second conductive via 262, respectively. In some embodiments, the signal line 224c may optionally be formed within the insulating layer 244.

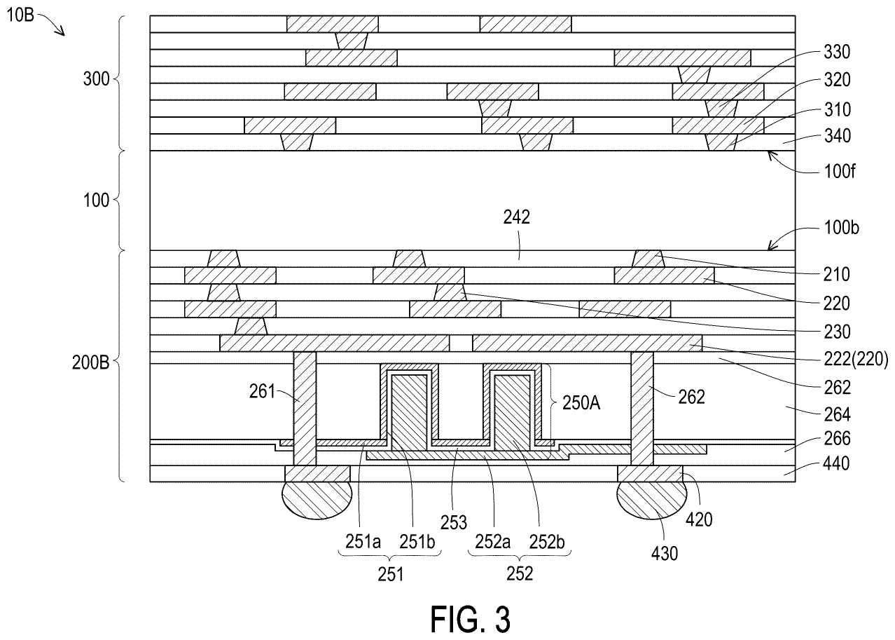

FIG. 3 is a schematic cross-sectional view of a semiconductor device 10B according to some embodiments of the present disclosure. The semiconductor device 10B in FIG. 3 is similar to the semiconductor device 10A in FIG. 1A, with the difference being that the MIM capacitor 250A is positioned closer to the bonding pads 420 in FIG. 3.

In the backside circuit structure 200B shown in FIG. 3, the first conductive via 261 and the second conductive via 262 connect the bonding pads 420 to the conductive pattern layer 222. In some embodiments, there are no additional interconnect layers between the MIM capacitor 250A and the bonding pads 420.

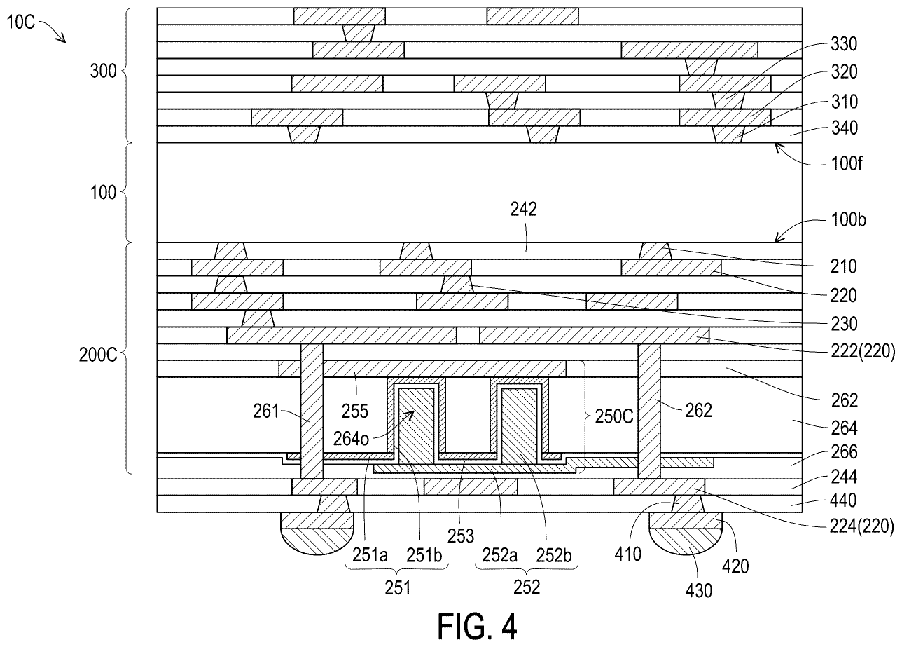

FIG. 4 is a schematic cross-sectional view of a semiconductor device 10C according to some embodiments of the present disclosure. The semiconductor device 10C in FIG. 4 is similar to the semiconductor device 10A in FIG. 1A, with the difference being that the MIM capacitor 250C further includes a conductive plate 255.

In the backside circuit structure 200C shown in FIG. 4, the conductive plate 255 is embedded in the bottom insulating layer 262. The conductive plate 255 connected to bottom surfaces of the liner portions 251b of the first electrode 251 at bottoms of the trenches 264o. A portion of the insulating structure 264 is laterally located between two of the trenches 264o and vertically located between the first electrode 251 and the conductive plate 255. The conductive plate 255 is separated from the dielectric layer 253 by the first electrode 251. The conductive plate 255 extends horizontally and has a lower resistance compared to the first electrode 251, which varies in elevation along the trenches 264o. Therefore, the presence of the conductive plate 255 can reduce the resistance of the MIM capacitor 250C.

In some embodiments, the conductive plate 255 may be composed of a single conductive layer or multiple conductive layers. For example, the materials for the conductive plate 255 may include Ti, TiN, TaN, Co, Ru, Pt, W, Al, Cu, or a combination of these, or other suitable conductive materials. In some embodiments, a thickness of the conductive plate 255 is greater than a thickness of the first electrode 251.

The first conductive via 261 is penetrating through the conductive plate 255, and the second conductive via 262 is separated from the conductive plate 255. The conductive plate 255 is in contact with the sidewall of the first conductive via 261. In other embodiments, the first conductive via 261 does not pass through the conductive plate 255 and terminates at the conductive plate 255.

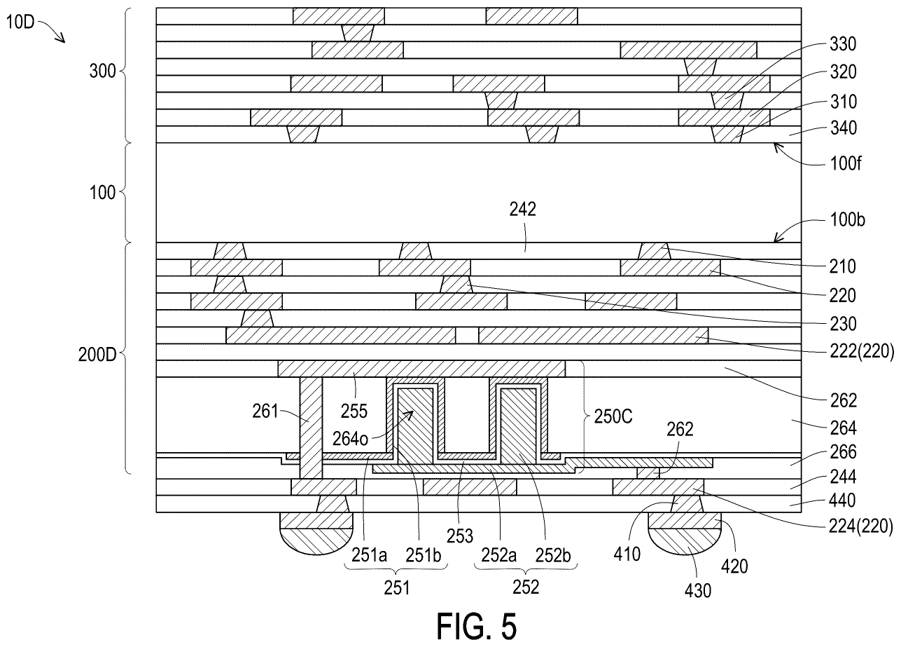

FIG. 5 is a schematic cross-sectional view of a semiconductor device 10D according to some embodiments of the present disclosure. The semiconductor device 10D depicted in FIG. 5 is similar to the semiconductor device 10C shown in FIG. 4, with the distinction that in the semiconductor device 10D, the first conductive via 261 and the second conductive via 262 terminate on the conductive plate 255 and the second electrode 252, respectively.

In the backside circuit structure 200D illustrated in FIG. 5, the first conductive via 261 does not penetrate through the conductive plate 255 but rather contacts the top surface of the conductive plate 255. Additionally, the second conductive via 262 does not pass through the second electrode 252 but instead contacts the top surface of the second electrode 252.

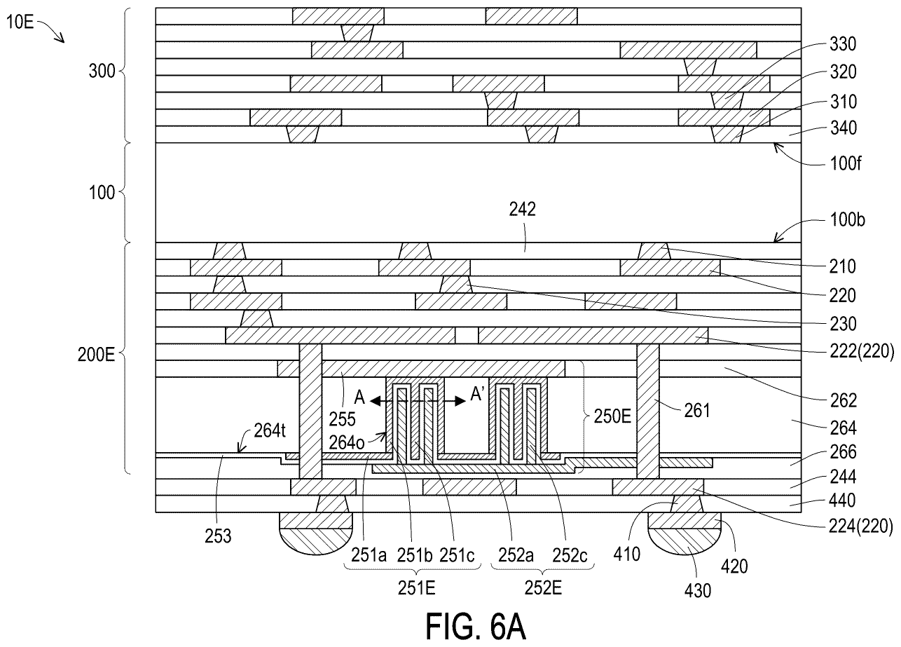

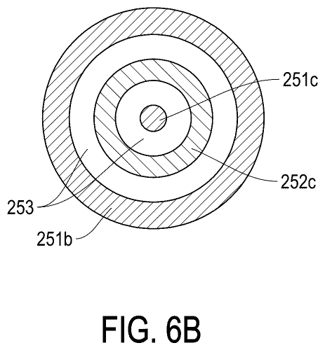

FIG. 6A is a schematic cross-sectional view of a semiconductor device 10E according to some embodiments of the present disclosure. FIG. 6B is a schematic cross-sectional view along line A-A′ of FIG. 6A. The semiconductor device 10E illustrated in FIG. 6A is similar to the semiconductor device 10C presented in FIG. 4. The difference is that in the semiconductor device 10E, the first electrode 251E of the MIM capacitor 250E includes protruding portions 251c, which are designed to enhance the capacitance value.

Referring to FIGS. 6A and 6B, the first electrode 251E includes an extending portion 251a, multiple liner portions 251b and multiple protruding portions 251c. The extending portion 251a is located on the top surface 264t of the insulating structure 264, while the liner portions 251b are situated within the trenches 264o and connected to the extending portion 251a. The liner portions 251b cover the bottom surfaces and sidewalls of the trenches 264o. The protruding portions 251c are located within the trenches 264o and extend upward from the liner portions 251b at the bottom of the trenches 264o.

The dielectric layer 253 is disposed over the first electrode 251E. The second electrode 252E is disposed over both the first electrode 251E and the dielectric layer 253. The second electrode 252E includes several plug portions 252c and a plate portion 252a. The plug portions 252c are located within the trenches 264o, while the plate portion 252a is positioned above the top surface 264t of the insulating structure 264 and connected to the plug portions 252c. Each of the plug portions 252c surrounds a corresponding one of the protruding portions 251c. In FIG. 6B, the liner portion 251b and the plug portion 252c feature annular structures, forming concentric rings centered around the protruding portion 251c.

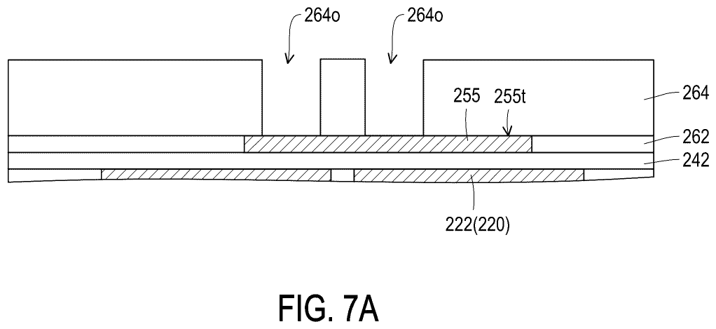

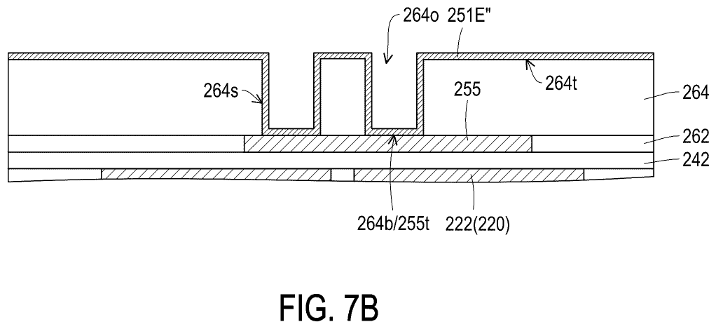

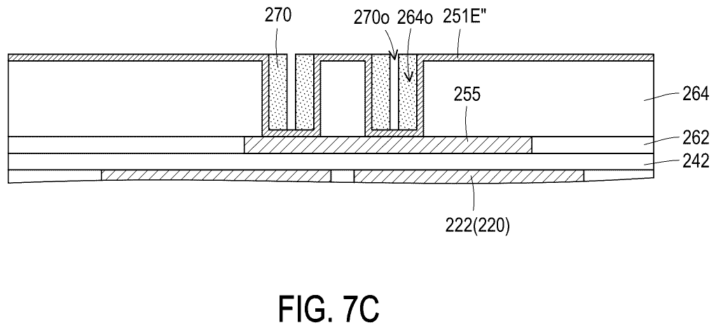

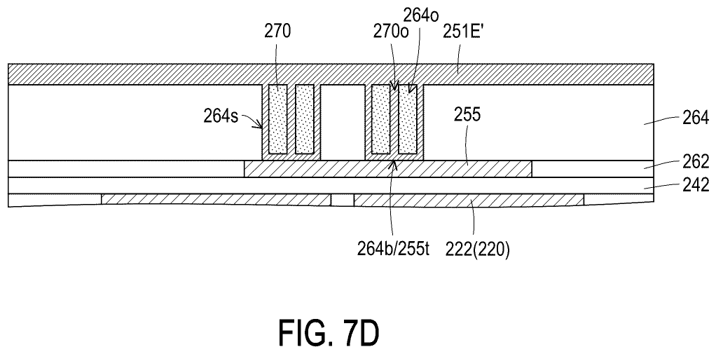

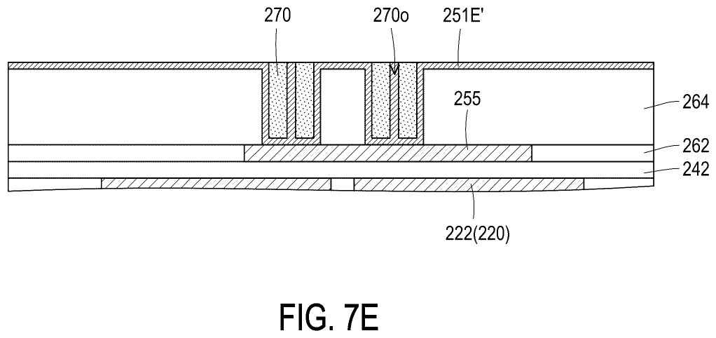

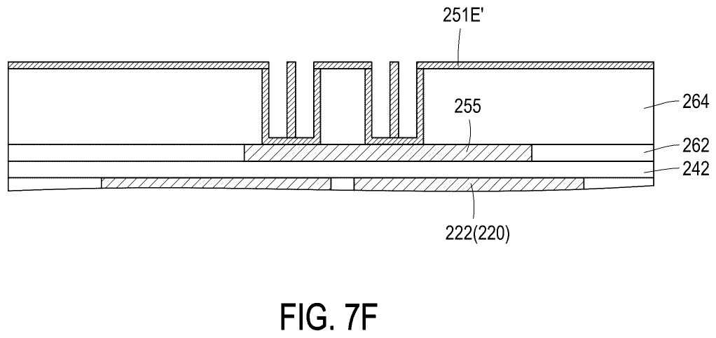

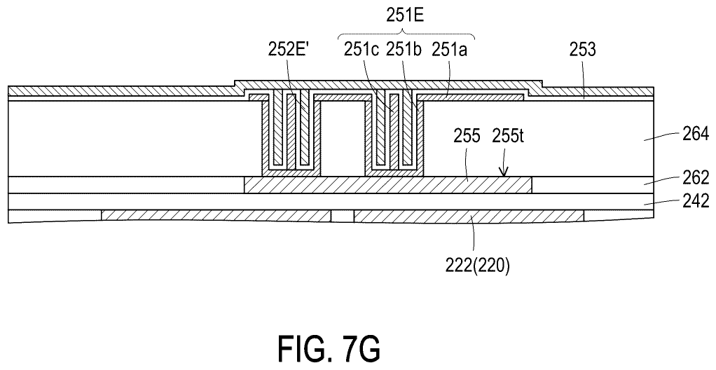

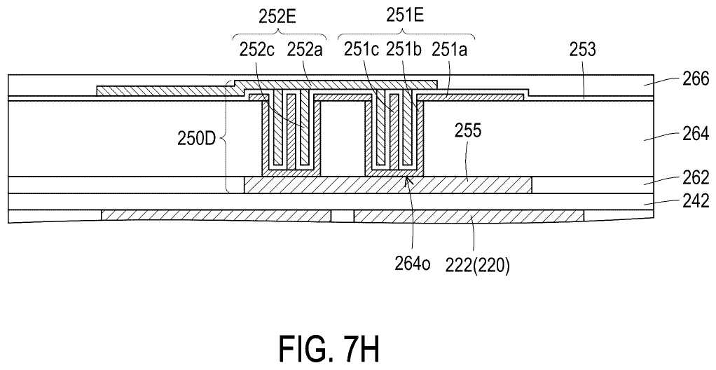

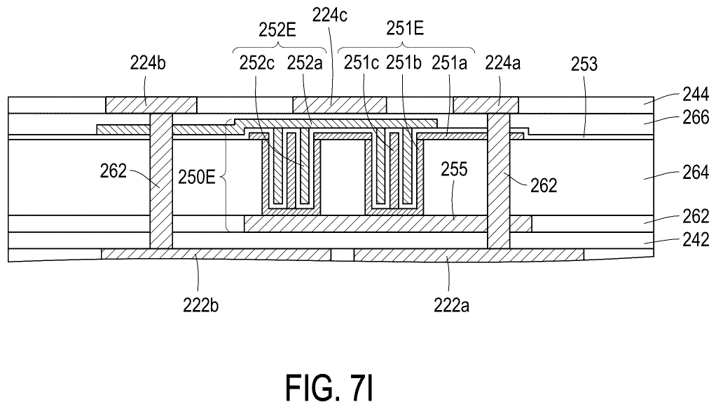

FIGS. 7A to 7I present schematic cross-sectional views depicting various stages in the fabrication method of the MIM capacitor within the backside circuit structure of certain embodiments of the present disclosure. Specifically, these figures illustrate the different stages involved in forming the MIM capacitor 250E within the backside circuit structure 200E, as shown in FIG. 6A. The fabrication method of the backside circuit structure 200E encompasses the various steps for forming the MIM capacitor 250E, as depicted in FIGS. 7A to 7I.

As illustrated in FIG. 7A, the bottom insulating layer 262, the conductive plate 255, and the insulating structure 264 are formed on the insulating layers 242 and the conductive pattern layer 222. In some embodiments, the conductive pattern layer 222 is embedded within the insulating layer 242. In certain implementations, a front side circuit structure 300 is first formed on the front side 100f of the semiconductor structure 100, followed by the formation of the conductive pattern layers 220 and vias 230 located beneath the conductive pattern layer 222 on the backside 100b of the semiconductor structure 100, as shown in FIGS. 1A and 2A. Subsequently, the conductive pattern layer 222 and the insulating layer 242 located above the conductive pattern layer 222 are formed, and the bottom insulating layer 262 and the conductive plate 255 are formed over the conductive pattern layer 222 and the insulating layer 242. The insulating structure 264 is formed above the conductive plate 255. The trenches 264o of the insulating structure 264 expose a top surface 255t of the conductive plate 255.

The trenches 264o in the insulating structure 264 may be created using lithography processes, etch processes, or other suitable methods. In certain embodiments, the depth of the trenches 264o ranges from 100 nm to 10,000 nm.

Referring to FIG. 7B, a first conductive layer 251E″ is formed on the top surface 264t of the insulating structure 264, covering both the bottom surfaces 264b and the sidewalls 264s of the trenches 264o. In this embodiment, the top surface 255t of the conductive plate 255 and the bottom surfaces 264b of the trenches 264o are essentially coplanar. The first conductive layer 251E″ is in contact with the top surface 255t of the conductive plate 255 through the trenches 264o.

Referring to FIG. 7C, a spacer layer 270 is formed on the first conductive layer 251E″ in the trenches 264o. The spacer layer 270 includes openings 2700 located in the trenches 264o. The openings 2700 expose the first conductive layer 251E″ at the bottom of the trenches 264o. In some embodiments, the spacer layer 270 is formed through dielectric deposition and etch-back process.

Referring to FIG. 7D, a conductive material is deposited on the first conductive layer 251E″ and within the openings 2700 to form a second conductive layer 251E′. The second conductive layer 251E′ includes the first conductive layer 251E″ as well as the conductive material deposited on it, which may be the same as or different from the material of the first conductive layer 251E″. The second conductive layer 251E′ covers the bottom surface 264b and sidewalls 264s of the trenches 264o, and it fills the openings 2700 of the spacer layer 270.

Referring to FIG. 7E, a part of the second conductive layer 251E′ beyond the spacer layer 270 is removed to expose the spacer layer 270. In some embodiments, the part of the second conductive layer 251E′ is removed through etch-back process, chemical mechanical polishing (CMP), or other suitable process.

Referring to FIG. 7F, the spacer layer 270 is removed.

Referring to FIG. 7G, patterning the second conductive layer 251E′ to form the first electrode 251E, which includes an extending portion 251a, liner portions 251b and protruding portions 251. The liner portions 251b are connected to the top surface 255t of the conductive plate 255.

In some embodiments, the methods for patterning the second conductive layer 251E′ include wet etch, dry etch, or a combination of both.

A dielectric layer 253 is formed on the first electrode 251. A third conductive layer 252E′ is formed on the dielectric layer 253. The third conductive layer 252E′ overlaps the first electrode 251E.

Referring to FIG. 7H, the third conductive layer 252E′ is patterned to form the second electrode 252E, which includes several plug portions 252c and a plate portion 252a. The plug portions 252c are located in the trenches 264o and surround the protruding portions 251c. A part of the dielectric layer 253 is disposed between the first electrode 251E and the second electrode 252E. In some embodiments, the methods for patterning the third conductive layer 252E′ include wet etch, dry etch, or a combination of both.

The capping layer 266 is formed over the second electrode 252E.

Referring to FIG. 7I, the first conductive via 261 and the second conductive via 262 are formed. For example, an opening is formed through the insulating layer 242, the conductive plate 255, the insulating structure 264, the first electrode 251E, the dielectric layer 253, and the capping layer 266. Then, a conductive material is filled into this opening to form the first conductive via 261. Similarly, another opening is formed through insulating layer 242, the bottom insulating layer 262, the insulating structure 264, the second electrode 252, the dielectric layer 253, and the capping layer 266, followed by filling a conductive material into this opening to form the second conductive via 262. The first conductive via 261 and the second conductive via 262 are respectively located above the first power line 222a and the second power line 222b.

In this embodiment, the openings used to accommodate the first conductive via 261 and the second conductive via 262 are positioned over the first power line 222a and the second power line 222b, respectively; however, this disclosure is not limited thereto. In other embodiments, the openings for the first conductive via 261 and the second conductive via 262 may be aligned with the conductive plate 255 and the second electrode 252E, without penetrating through the conductive plate 255 and the second electrode 252E. This arrangement allows the subsequently filled conductive materials to make contact with the top surface of the conductive plate 255 and the top surface of the second electrode 252E, similar to the configuration shown in FIG. 5 for the first conductive via 261 and the second conductive via 262.

The insulating layer 244 is formed over the capping layer 266. The third power line 224a and the fourth power line 224b are embedded within the insulating layer 244 and are positioned directly above the first conductive via 261 and the second conductive via 262, respectively. In some embodiments, the signal line 224c may optionally be formed within the insulating layer 244.

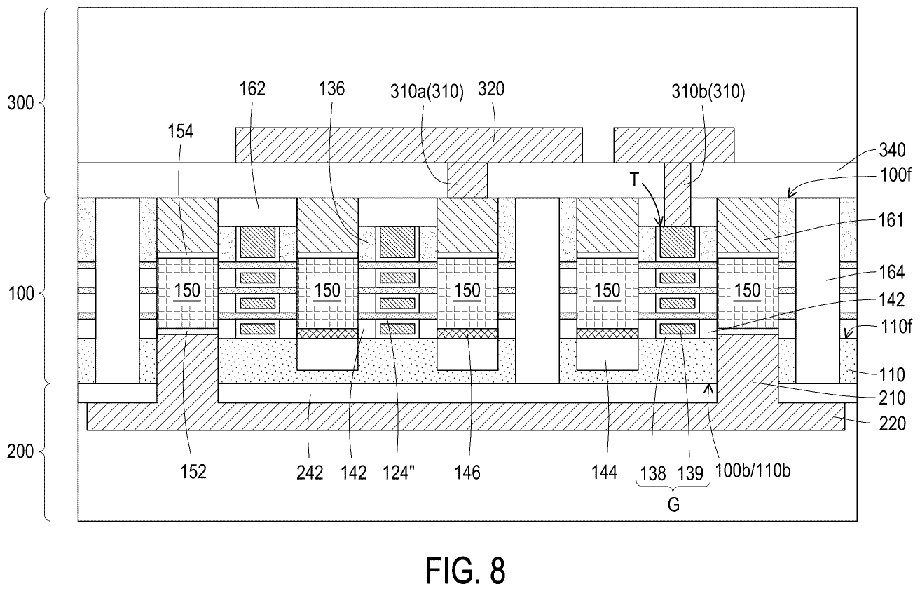

FIG. 8 is a schematic cross-sectional view of a semiconductor device according to some embodiments of the present disclosure. FIG. 8 illustrates an exemplary structure of the semiconductor structure 100, briefly depicting the front side circuit structure 300 and the backside circuit structure 200. The backside circuit structure 200 in FIG. 8 can be substituted with any of the previously described backside circuit structures, including 200A in FIG. 1A, 200B in FIG. 3, 200C in FIG. 4, 200D in FIG. 5, or 200E in FIG. 6A. Similarly, the front side circuit structure 300 in FIG. 8 may be replaced by any of the front side circuit structures from earlier embodiments.

Referring to FIG. 8, the semiconductor structure 100 includes a substrate 110 and multiple transistors T formed along the front side 110f of the substrate 110. In some embodiments, the substrate 110 may be composed of materials such as silicon, germanium, silicon carbide, gallium nitride, gallium arsenide, or other semiconductor materials.

Each of the transistors T features channel structures 124″, a gate structure G, and source/drain structures 150. The gate structures G are arranged along the front side 110f of the substrate 110. The channel structures 124″ may be nanosheets, nanowires, or other types of channel structures. In this embodiment, the channel structures 124″ are nanosheets. The number of channel structures 124″ in each transistor T can be adjusted according to actual requirements, for example, ranging from 2 to 6 channel structures 124″. In this embodiment, each transistor T includes 3 channel structures 124″. In some embodiments, a channel width (sheet width) of the transistor T is in a range between 4 nm to 70 nm. In some embodiments, a thickness of each channel structure 124″ (sheet thickness) is in a range between 4 nm to 8 nm. In some embodiments, a vertical distance between two adjacent channel structures 124″ is in a range between 6 nm to 15 nm. In some embodiments, a vertical pitch between two adjacent channel structures 124″ is in a range between 10 nm to 23 nm.

The gate structure G surrounds the channel structures 124″ and forms a GAA structure. Each gate structure G includes a gate dielectric layer 138 and a gate electrode layer 139. In some embodiments, a gate length of the transistor T is in a range between 6 nm to 40 nm.

The inner spacers 142 and the top spacers 136 are disposed on the sidewalls of the gate structure G. Specifically, the top spacers 136 are located above the channel structures 124″, while the inner spacers 142 are located between the channel structures 124″ and between the channel structures 124″ and the substrate 110. In some embodiments, a thickness (in horizontal direction) of the inner spacers 142 and the top spacers 136 is in a range between 4 nm to 12 nm. In some embodiments, the material for the inner spacers 142 is selected from a group consisting of SiO₂, Si₃N₄, SION, SiOC, SiOCN-based dielectric materials, air gaps, or a combination thereof. In some embodiments, the material for the top spacers 136 is selected from a group consisting of SiO₂, Si₃N₄, carbon doped oxide, nitrogen doped oxide, porous oxide, air gap, or a combination thereof. In some embodiments, the effective dielectric constant of the inner spacers 142 is higher than that of the top spacers 136.

In some embodiments, sacrificial layers 144 are located beneath certain source/drain structures 150. For instance, the sacrificial layers 144 are located along the front side 110f of the substrate 110, with bottom dielectric layers 146 interposed between them and their corresponding source/drain structures 150. In some cases, the materials used for the sacrificial layers 144 may include SiGe or other suitable materials.

Source/drain contacts 161 are located over the source/drain structures 150. In some embodiments, front-side silicide layers 154 are interposed between the source/drain contacts 161 and the source/drain structures 150.

Hard mask layer 162 is disposed over the gate structures G. Dielectric-base gates 164 are formed to separate the gate structures G. The dielectric-base gates 164 include dielectric materials and can be formed by various steps including lithography, etch, deposition, etc. The material of the dielectric-base gates 164 is different from that of the gate electrodes 139. In some embodiments, the dielectric-base gates 164 can be interchangeably referred to dummy gates, dummy gate pattern, dummy gate strip, isolation structures/dielectric gates serving as circuit boundaries. The inner spacers 142 and the top spacers 136 are also formed on sidewalls of the dielectric-base gates 225.

The front side circuit structure 300 is located over the gate structures G of the transistors T. The contact vias 310 of the front side circuit structure 300 are electrically connected to the transistors T. For example, the source/drain contact vias 310a are electrically connected to a portion of the source/drain contacts 161, which further electrically connect to the source/drain structures 150 of the transistors T. The gate contact vias 310b are electrically connected to a portion of the gate structures G of the transistors T. In some embodiments, the materials for the source/drain contact vias 310a, the gate contact vias 310b, and the source/drain contacts 161 include one or more metal materials, such as Ti, TiN, TaN, Co, Ru, Pt, W, Al, Cu, or a combination thereof.

In some embodiments, both the source/drain contact vias 310a and the gate contact vias 310b pass through the insulating layer 340 closest to the semiconductor structure 100, which can be referred to as the interlayer dielectric (ILD) layer. Additionally, in some embodiments, the gate contact vias 310b not only traverse the ILD layer but also penetrate the hard mask layer 162 to make contact with the gate structures G.

The backside circuit structure 200 is disposed on the backside 100b of the semiconductor structure 100 (or the backside 110b of the substrate 110). The backside circuit structure 200 includes one or more MIM capacitors and a power mesh that is electrically connected to the MIM capacitors, as illustrated in any of the previously described embodiments featuring MIM capacitors and a power mesh composed of multiple power lines.

In some embodiments, the backside contacts 210 of the backside circuit structure 200 are electrically connected to a portion of the source/drain structures 150, with back-side silicide layers 152 interposed therebetween. In some embodiments, the backside contacts 210 are passing through the substrate 110. In some embodiments, the portion of the source/drain structures 150 are electrically connected to the first power supply voltage VSS or the second power supply voltage VDD though the backside contacts 210.

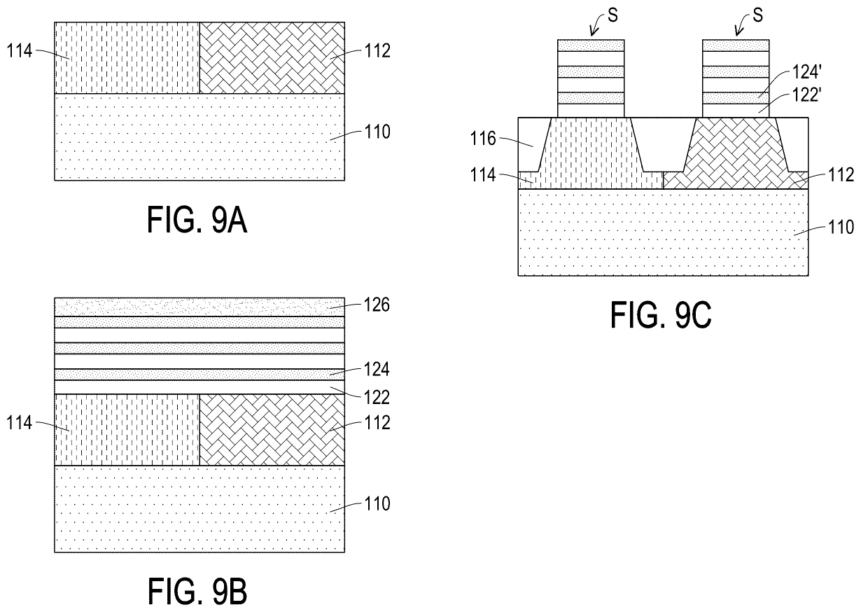

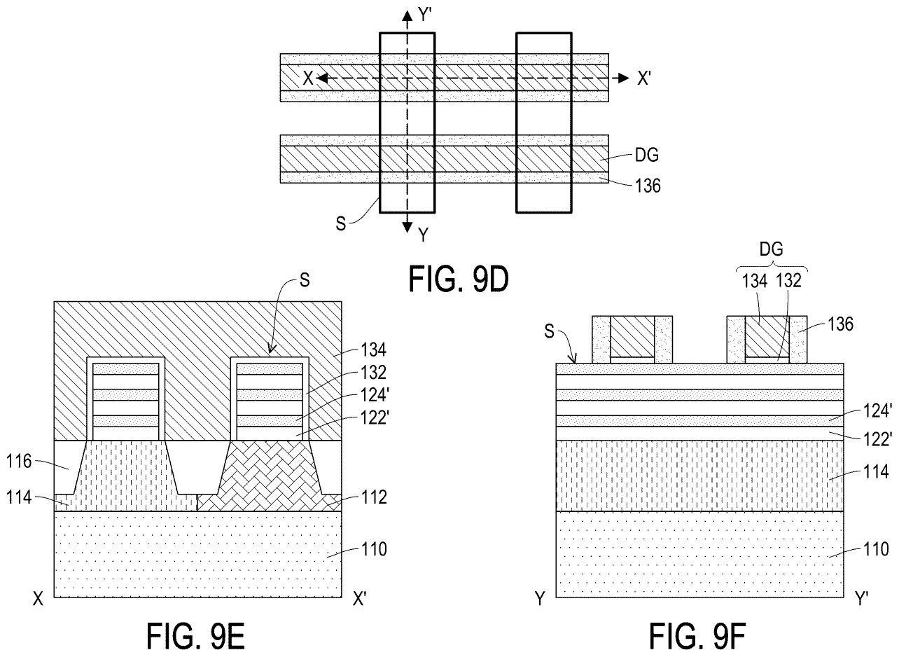

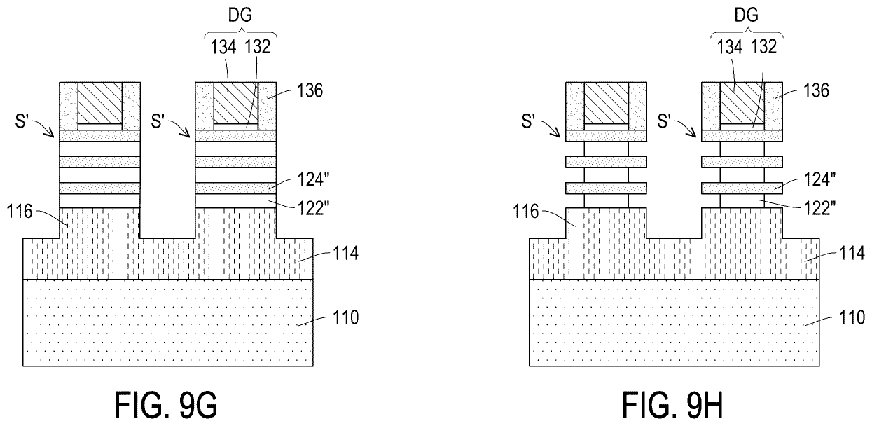

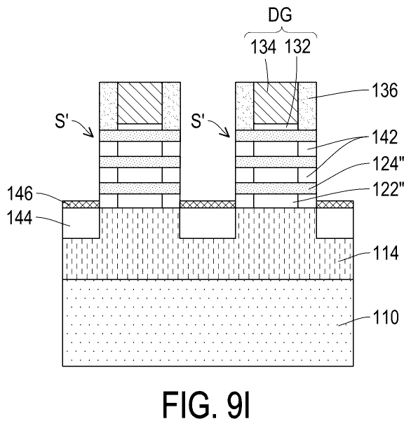

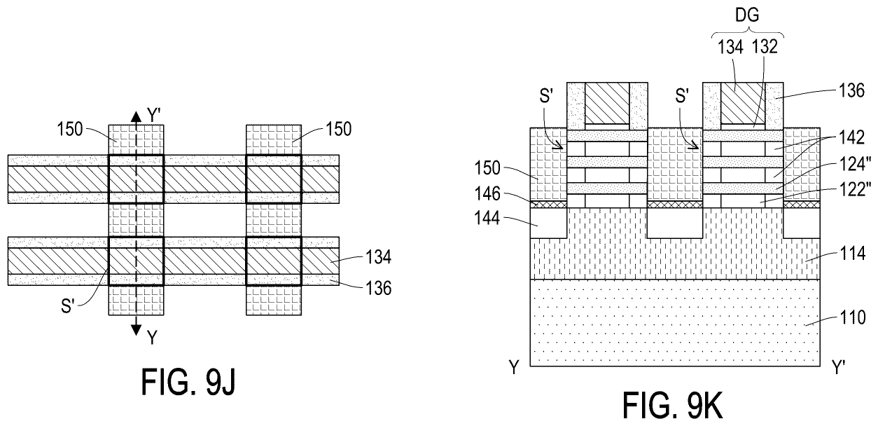

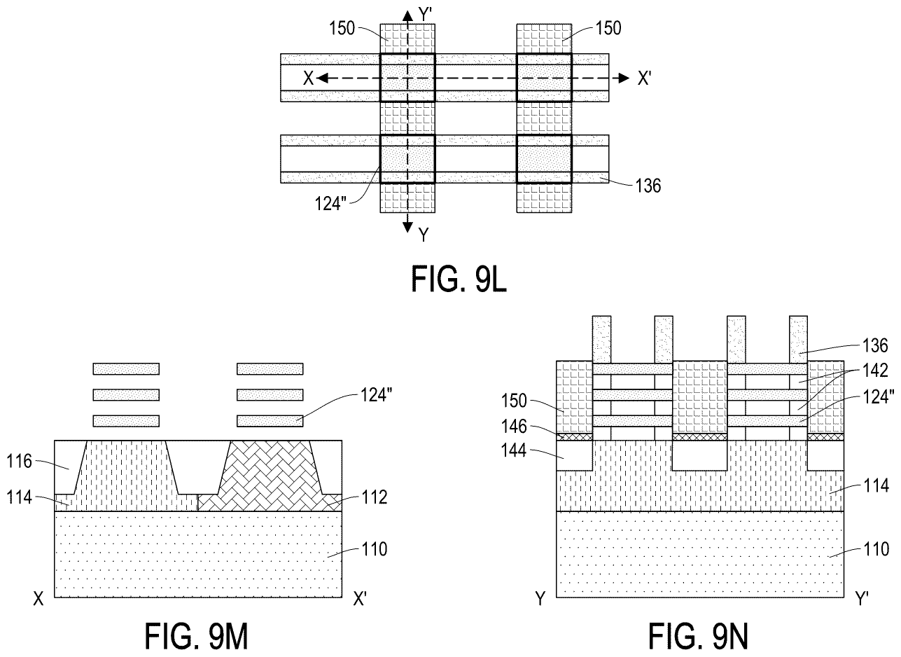

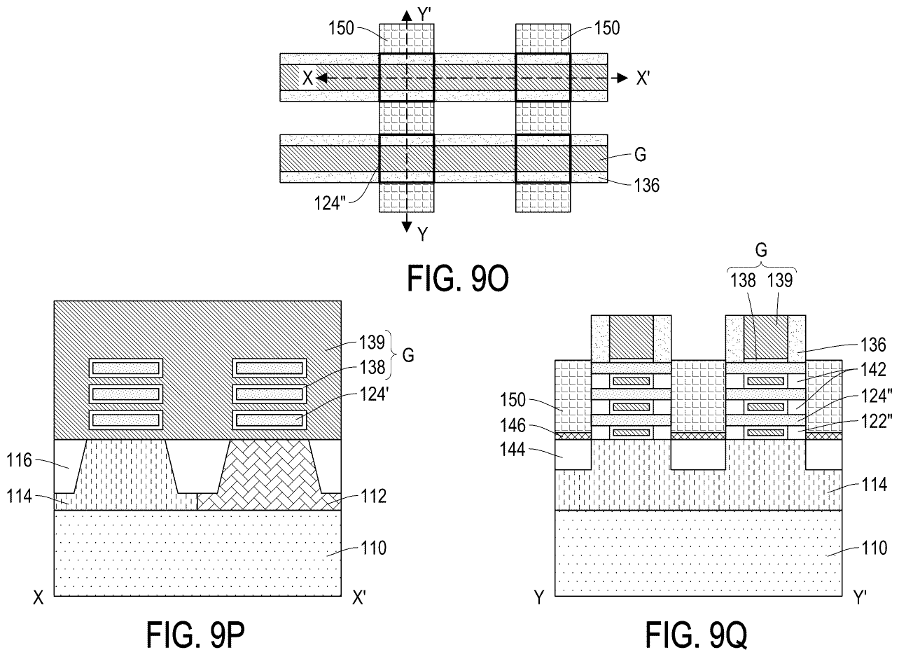

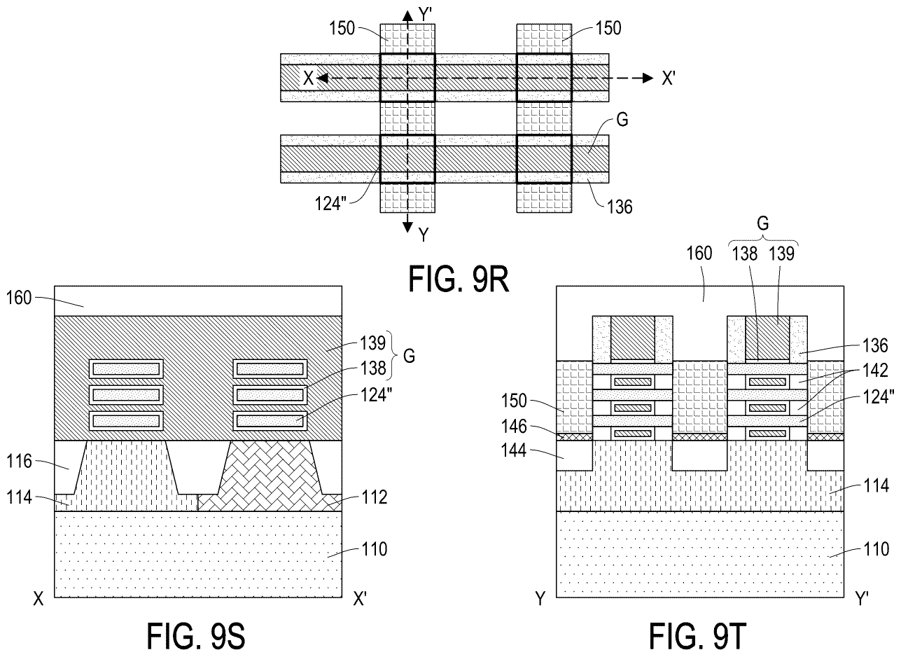

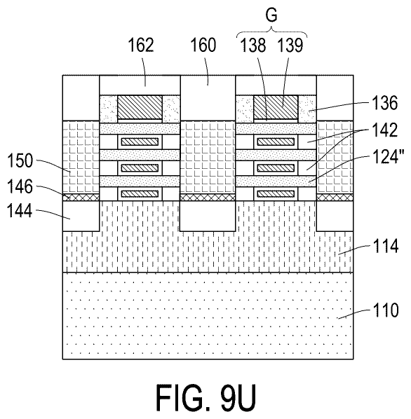

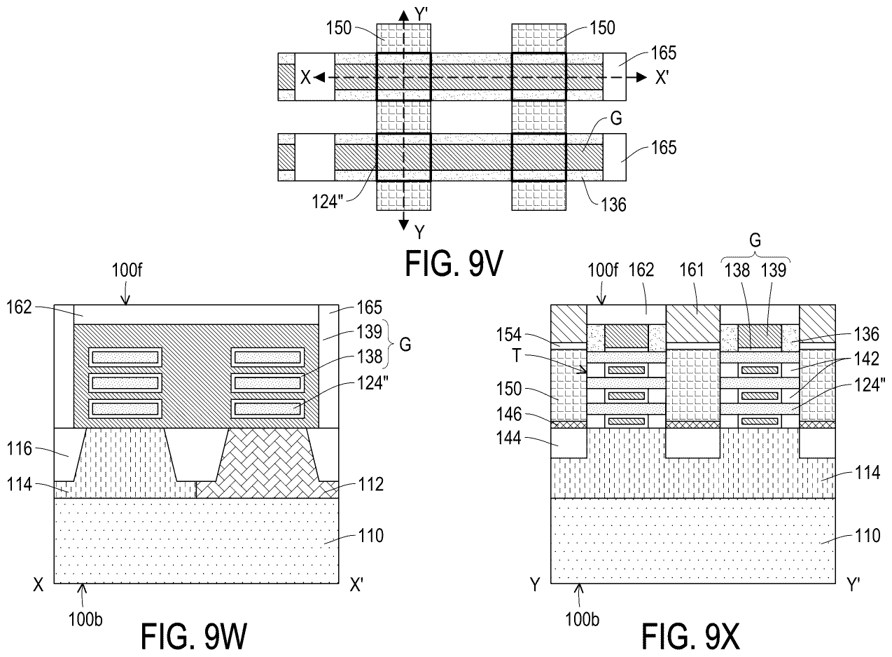

FIGS. 9A to 9T present various schematic diagrams depicting different stages of the fabrication method for transistors in a semiconductor structure, as outlined in some embodiments of the present disclosure. For example, these figures illustrate the various stages involved in the manufacturing process of the transistors T shown in FIG. 8. FIGS. 9A to 9C are schematic cross-sectional views of various stages of the fabrication method of the transistors. Referring to FIG. 9A, an N-type well 114 and a P-type well 112 are formed in the substrate 110. In some embodiments, the process for forming the N-type well 114 and the P-type well 112 involves multiple lithography and implantation steps.

Referring to FIG. 9B, a stack is formed that includes multiple channel material layers 124 and sacrificial layers 122, arranged in an alternating manner. In some embodiments, the channel material layers 124 consist of silicon (Si), while the sacrificial layers 122 comprise silicon germanium (SiGe); however, this disclosure is not limited to these materials. Other materials may be chosen for the channel material layers 124 and sacrificial layers 122 in different embodiments. The channel material layers 124 and sacrificial layers 122 exhibit a high etch selectivity ratio, facilitating the selective removal of the sacrificial layers 122 in subsequent processing steps. In some cases, the channel material layers 124 and sacrificial layers 122 are formed using multiple epitaxial growth processes.

A hard mask layer 126 is then formed on top of the stack of the channel material layers 124 and the sacrificial layers 122. In some embodiments, the hard mask layer 126 consists of insulating materials.

Referring to FIG. 9C, the stack of channel material layers 124 and sacrificial layers 122 is patterned through lithography and etch processes to form semiconductor stacks S that are spaced apart. Each semiconductor stack S consists of patterned channel material layers 124′ and patterned sacrificial layers 122′.

Shallow trench isolation (STI) structures 116 are formed in the substrate 110 between the semiconductor stacks S. In some embodiments, the method for forming the STI structures 116 involves dielectric deposition, chemical mechanical polishing (CMP), and STI etch-back processes. In some embodiments, the depth of the STI structures 116 ranges from 20 nm to 80 nm. The hard mask layer 126 is then removed.

FIGS. 9D to 9F illustrate various views of a step in the fabrication method of the transistors, with FIG. 9D showing a top-down schematic, while FIGS. 9E and 9F provide cross-sectional views along lines X-X′ and Y-Y′, respectively, in FIG. 9D. Referring to FIGS. 9D to 9F, dummy oxide layers 132 and dummy gates 134 are formed on the semiconductor stacks S. In some embodiments, each dummy oxide layer 132, together with the corresponding dummy gate 134 stacked above it, forms a dummy gate stack DG. Each dummy gate stack DG crosses multiple semiconductor stacks S.

Top spacers 136 are formed on the sidewalls of the dummy gate stacks DG. In some embodiments, the method for forming the top spacers 136 involves dielectric deposition and etch-back processes.

FIGS. 9G to 9I are cross-sectional schematic diagrams showing subsequent processing steps corresponding to line Y-Y′ in FIG. 9D. Referring first to FIG. 9G, the semiconductor stacks S are etched using the dummy gate stacks DG and the top spacers 136 as a mask. In some embodiments, the etch extends into the substrate 110, including the N-type well 114 and the P-type well 112. In some cases, the etch depth into the substrate 110 may range from approximately 30 nm to 100 nm. After the etch, the semiconductor stacks S are transformed into the semiconductor stacks S′. The semiconductor stacks S′ comprise patterned channel material layers 124″ and patterned sacrificial layers 122″.

Next, referring to FIG. 9H, a sidewall pull-back process is performed on the semiconductor stacks S′, selectively removing portions of the patterned sacrificial layers 122″ while retaining the patterned channel material layers 124″. This results in a recessed profile at the sidewalls of the semiconductor stacks S′ at the patterned sacrificial layers 122″.

Referring to FIG. 9I, inner spacers 142 are formed on the sidewalls of the semiconductor stacks S′, located within the recesses at the patterned sacrificial layers 122″. In some embodiments, the method for forming the inner spacers 142 involves a dielectric deposition and an etch-back process.

FIGS. 9J and 9K illustrate various views of a step in the fabrication method of the transistors, with FIG. 9J showing a top-down schematic, while FIG. 9K provide cross-sectional views along the line Y-Y′ in FIG. 9J. Referring to FIGS. 9J and 9K, sacrificial layers 144 and bottom dielectric layers 146 are formed. In some embodiments, the sacrificial layers 144 fill the trenches formed by etching the surface of the substrate 110, and the bottom dielectric layers 146 are formed on top of the sacrificial layers 144. In some embodiments, the thickness of the sacrificial layers 144 are ranges from 30 nm to 100 nm. The source/drain structures 150 are then formed above the bottom dielectric layer 146 and between the semiconductor stacks S′.

In some embodiments, the source/drain structures 150 on the N-type well 114 (for example, the left column of source/drain structures 150 in FIG. 9J) and those on the P-type well 112 (refer to FIG. 9A; for example, the right column of source/drain structures 150 in FIG. 9J) are formed using different epitaxial processes. For instance, one set may be formed through an N-epitaxy process, while the other set may be formed using a P-epitaxy process; however, this disclosure is not limited thereto. In some embodiments, for an N-type Metal-Oxide-Semiconductor Field-Effect Transistor (NMOSFET), the epitaxial material used to form the source/drain structures 150 includes SiP, SiC, SiPC, SiAs, Si, or a combination thereof, or other suitable materials. In some embodiments, for a P-type Metal-Oxide-Semiconductor Field-Effect Transistor (PMOSFET), the epitaxial material used to form the source/drain structures 150 includes SiGe with boron content, or SiGe with boron and carbon contents, or other suitable materials.

FIGS. 9L to 9N illustrate various views of a step in the fabrication method of the transistors, with FIG. 9L showing a top-down schematic, while FIGS. 9M and 9N provide cross-sectional views along lines X-X′ and Y-Y′, respectively, in FIG. 9L. Referring to FIGS. 9L to 9N, the dummy gate stack DG and the patterned sacrificial layers 122″ are removed.

FIGS. 9O to 9Q illustrate various views of a step in the fabrication method of the transistors, with FIG. 9O showing a top-down schematic, while FIGS. 9P and 9Q provide cross-sectional views along lines X-X′ and Y-Y′, respectively, in FIG. 9O. Referring to FIGS. 9O to 9Q, gate structures G are formed. Each of the gate structure G includes a gate dielectric layer 138 and a gate electrode layer 139. In some embodiments, the gate electrode layers 139 may comprise a single conductive material or multiple conductive materials. In some embodiments, the material of the gate electrode layers 139 above the N-type well 114 differs from the material of the gate electrode layers 139 above the P-type well 112. In other words, the gate electrode layers 139 can be formed through multiple metal deposition processes combined with patterning processes.

The gate electrode layers 139 may include a metal-containing material such as titanium nitride, titanium oxide, tungsten, cobalt, ruthenium, aluminum, combinations thereof, multi-layers thereof, or the like. Although a single-layered gate electrode layer 139 is illustrated in FIGS. 9P and 9Q, the gate electrode layer 139 may include any number of work function tuning layers, any number of barrier layers, any number of glue layers, and a fill material. In some embodiments, the gate electrode layer 139 may be made of a material selected from a group including TiN, TaN, TiAl, TiAlN, TaAl, TaAlN, TaAlC, TaCN, WNC, Co, Ni, Pt, W, or combinations thereof. The NMOSFET and the PMOSFET can be formed by same work function material, or different materials.

FIGS. 9R to 9T illustrate various views of a step in the fabrication method of the transistors, with FIG. 9R showing a top-down schematic, while FIGS. 9S and 9T provide cross-sectional views along lines X-X′ and Y-Y′, respectively, in FIG. 9R. Referring to FIGS. 9R to 9T, an interlayer dielectric (ILD) layer 160 is then formed over the gate structure G.

FIG. 9U is a cross-sectional schematic diagram showing the subsequent processing steps along line Y-Y′ in FIG. 9T. Referring to FIG. 9U, an etch-back process is performed on the gate dielectric layers 138 and gate electrode layers 139 to scale down the gate structures G. The etch-back process may include a bias plasma etch step. The bias plasma etch step may be performed to remove portions of the gate dielectric layers 138 and the gate electrode layers 139, forming recessed areas above the gate electrode layers 139 and the top spacers 136. Top surfaces of the gate dielectric layers 138 and the gate electrode layers 139 may be no longer level with the ILD layer 160. In some embodiments, the bias plasma etch step may use a gas mixture of Cl₂, O₂, BCl₃, and Ar with a bias in a range from about 25V to about 1200V.

The hard mask layer 162 is formed over the gate dielectric layers 138 and the gate electrode layers 139 using, for example, a deposition process to deposit a dielectric material over the substrate 110, followed by a CMP process to remove excess dielectric material above the ILD layer 160.

FIGS. 9V to 9X illustrate various views of a step in the fabrication method of the transistors, with FIG. 9V showing a top-down schematic, while FIGS. 9W and 9X provide cross-sectional views along lines X-X′ and Y-Y′, respectively, in FIG. 9V. Referring to FIGS. 9V to 9X, gate-cut structures 165 are formed by a cut metal gate (CMG) process. In some embodiments, the gate-cut structures 165 may be made of an oxide, such as SiO₂, or a nitride-based material, such as Si₃N₄, SiON, or a carbon-based material, such as SiC, SiOC, SiOCN, or combinations thereof, or other suitable material. In some embodiments, the gate-cut structures 165 may be made of a material having a dielectric constant greater than about 9 (e.g., high dielectric constant (high-k) material). For example, the gate-cut structures 165 may be made of a high dielectric constant (high-k) material, such as hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. In some embodiments, the gate-cut structures 165 are formed on opposite ends of the gate structures G after the forming of the hard mask layer 162.

The front-side silicide layers 154 and the source/drain contacts 161 are formed subsequently by a self-aligned contact process using the hard mask layer 162 as a contact etch protection layer. In some embodiments, the hard mask layer 162 may have a thickness in a range from about 2 nm to about 60 nm. In some embodiments, the hard mask layer 162 may be made of an oxide-based material, such as SiOx, or a nitride-based material, such as Si₃N₄, SiON, or a carbon-based material, such as SiC, SiOC, SiOCN, or combinations thereof. In some embodiments, the hard mask layer 162 may include SiBN, SiCBN, other suitable dielectric materials, or combinations thereof. In some embodiments, the hard mask layer 162 may include a metal oxide, such as be hafnium oxide (HfO₂), zirconium oxide (ZrO₂), lanthanum oxide (La₂O₃), yttrium oxide (Y₂O₃), aluminum oxide (Al₂O₃), tantalum oxide (Ta₂O₅), titanium oxide (TiO₂), another applicable material, or combinations thereof. The hard mask layer 162 has different etch selectivity than the top spacers 136 and/or the ILD layer 160, so as to selective etch back the hard mask layer 162. By way of example, if the hard mask layer 162 is made of silicon nitride, the top spacers 136 and/or the ILD layer 160 may be made of a dielectric material different from silicon nitride. If the hard mask layer 162 is made of silicon carbide (SiC), the top spacers 136 and/or the ILD layer 160 may be made of a dielectric material different from silicon carbide. Therefore, the hard mask layer 162 can be used to define self-aligned gate contact region and thus referred to as a self-aligned contact (SAC) structure or a SAC layer. In some embodiments, the hard mask layer 162 can be interchangeably referred to a gate-top dielectric layer.

In some embodiments, a metal silicidation process can be performed on the the source/drain structures 150 to form the front-side silicide layers 154. The metal silicidation process is to make a reaction between metal and silicon (or polycrystalline silicon). In some embodiments, the front-side silicide layers 154 may include titanium silicide (TiSi), nickel silicide (NiSi), cobalt silicide (CoSi), Ni—Pt, or combinations thereof.

After completing the transistor T in FIGS. 9V to 9X, the front-side circuit structure 300 is formed on the front side 100f of the semiconductor structure 100, followed by the formation of the backside circuit structure 200 on the backside 100b of the semiconductor structure 100, as shown in FIG. 8. In some embodiments, before forming the backside circuit structure 200, a portion of the sacrificial layers 144 are removed, allowing the backside contacts 210 to be electrically connected to the corresponding source/drain structures 150. In some embodiments, before forming the backside circuit structure 200, an etch-back process is performed on the backside 100b of the semiconductor structure 100 to expose the sacrificial layers 144 and/or the STI structures 116 from the backside 100b. Optionally, after the etch-back process, an insulating layer is formed on the exposed STI structures 116 and the substrate 110.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

In some embodiments of the disclosure, a semiconductor device includes a semiconductor structure, a front side circuit structure and a backside circuit structure. The semiconductor structure includes a semiconductor transistor. The front side circuit structure is disposed over and electrically connected to a gate structure of the semiconductor transistor. The backside circuit structure is disposed on a backside of the semiconductor structure. The backside circuit structure includes a MIM capacitor and a power line electrically connected to the MIM capacitor. The MIM capacitor includes a first electrode, a second electrode and a dielectric layer, wherein the dielectric layer is disposed between the first electrode and the second electrode.

In some embodiments of the disclosure, a fabrication method of a semiconductor device includes forming a semiconductor structure including a semiconductor transistor and forming a circuit structure including a MIM capacitor and a power line on a backside of the semiconductor structure. A method for forming the circuit structure includes the following steps. An insulating structure includes a plurality of trenches is formed. A first electrode including an extending portion and a plurality of liner portions is formed. The extending portion is located on a top surface of the insulating structure. The liner portions are disposed in the trenches and connected to the extending portion. The liner portions cover bottom surfaces and sidewalls of the trenches. A dielectric layer is formed on the first electrode. A second electrode is formed on the dielectric layer. A part of the second electrode is located in the trenches, and a part of the dielectric layer is disposed between the first electrode and the second electrode.

In some embodiments of the disclosure, a fabrication method of a semiconductor device comprising providing a semiconductor structure including a semiconductor transistor, forming a front side circuit structure electrically connected to a gate structure of the semiconductor transistor, and forming a backside circuit structure on a side of the semiconductor structure opposite to the front side circuit structure. A method for forming the backside circuit structure includes the following steps. An insulating structure including a plurality of trenches is formed. A first electrode including an extending portion, a plurality of liner portions, and a plurality of protruding portions is formed. The extending portion is located on a top surface of the insulating structure. The liner portions are disposed in the trenches and connected to the extending portion. The liner portions cover the trenches. The protruding portions are disposed in the trenches. Gaps are laterally located between the liner portions and the protruding portions. A dielectric layer is formed on the extending portion, the liner portions and the protruding portions. A second electrode is formed on the dielectric layer. A part of the second electrode is located in the gaps, and the first electrode is separated from second electrode by the dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor structure comprising a semiconductor transistor;
a front side circuit structure, disposed over and electrically connected to a gate structure of the semiconductor transistor; and
a backside circuit structure, disposed on a backside of the semiconductor structure, wherein the backside circuit structure comprises a metal-insulator-metal capacitor and a power line electrically connected to the metal-insulator-metal capacitor, wherein the metal-insulator-metal capacitor comprises a first electrode, a second electrode and a dielectric layer, wherein the dielectric layer is disposed between the first electrode and the second electrode.

2. The semiconductor device of claim 1, wherein the backside circuit structure further comprises an insulating structure, and the first electrode is disposed in a plurality of trenches of the insulating structure, wherein the first electrode covers bottom surfaces and sidewalls of the plurality of trenches; wherein the second electrode is disposed over the first electrode, and comprising:
a plurality of plug portions, disposed in the plurality of trenches; and
a plate portion, disposed over a top surface of the insulating structure, and connected to the plurality of plug portions.

3. The semiconductor device of claim 2, wherein the backside circuit structure comprises:
a first conductive via and a second conductive via, disposed in and penetrating through the insulating structure, wherein the first electrode is connected to a sidewall of the first conductive via, and the second electrode is connected to a sidewall of the second conductive via.

4. The semiconductor device of claim 2, wherein the metal-insulator-metal capacitor comprises:
a conductive plate, connected to the first electrode at bottoms of the plurality of trenches, wherein a portion of the insulating structure is laterally located between two of the plurality of trenches and vertically located between the first electrode and the conductive plate.

5. The semiconductor device of claim 4, wherein a thickness of the conductive plate is greater than a thickness of the first electrode.

6. The semiconductor device of claim 4, wherein the backside circuit structure comprises:
a first conductive via, penetrating through the conductive plate, the insulating structure and the first electrode, wherein the first electrode and the conductive plate are connected to a sidewall of the first conductive via.

7. The semiconductor device of claim 2, wherein the first electrode comprises
an extending portion, located on the top surface of the insulating structure;
a plurality of liner portions, disposed in the plurality of trenches and connected to the extending portion, wherein the plurality of liner portions cover the bottom surfaces and the sidewalls of the plurality of trenches; and
a plurality of protruding portions, disposed in the plurality of trenches, wherein each of the plurality of plug portions surrounds a corresponding one of the plurality of protruding portions.

8. The semiconductor device of claim 7, wherein the metal-insulator-metal capacitor comprises:
a conductive plate, connected to bottom surfaces of the plurality of liner portions.

9. The semiconductor device of claim 2, wherein the backside circuit structure comprises:
a first conductive via and a second conductive via, disposed in and penetrating through the insulating structure, wherein the first electrode is connected to a sidewall of the first conductive via; and
a conductive plate, connected to the first electrode at bottoms of the plurality of trenches, wherein the first conductive via is in contact with a top surface of the conductive plate and the second conductive via is in contact with a top surface of the second electrode.

10. The semiconductor device of claim 1, further comprises:
a plurality of conductive terminals, disposed over the backside circuit structure, wherein the metal-insulator-metal capacitor is located between the plurality of conductive terminals and the semiconductor structure, wherein a backside contact of the backside circuit structure is electrically connected to a source/drain structure of the semiconductor transistor.

11. A fabrication method of a semiconductor device, comprising:
forming a semiconductor structure comprising a semiconductor transistor;
forming a circuit structure comprising a metal-insulator-metal capacitor and a power line on a backside of the semiconductor structure, wherein a method for forming the circuit structure comprises:
forming an insulating structure comprising a plurality of trenches;
forming a first electrode, wherein the first electrode comprises:
an extending portion, located on a top surface of the insulating structure; and
a plurality of liner portions, disposed in the plurality of trenches and connected to the extending portion, wherein the plurality of liner portions cover bottom surfaces and sidewalls of the plurality of trenches; and
forming a dielectric layer on the first electrode; and
forming a second electrode on the dielectric layer, wherein a part of the second electrode is located in the plurality of trenches, and a part of the dielectric layer is disposed between the first electrode and the second electrode.

12. The fabrication method of claim 11, wherein the method for forming the circuit structure further comprises:
forming a first conductive via penetrating through the first electrode and the insulating structure; and
forming a second conductive via penetrating through the second electrode and the insulating structure.

13. The fabrication method of claim 11, wherein the method for forming the circuit structure further comprises:
forming a conductive plate;
forming the insulating structure above the conductive plate, wherein the plurality of trenches expose a top surface of the conductive plate; and
forming the first electrode in the plurality of trenches, wherein the plurality of liner portions are connected to the top surface of the conductive plate.

14. The fabrication method of claim 13, wherein the method for forming the circuit structure further comprises:
forming a first conductive via penetrating through the dielectric layer, the first electrode, the insulating structure and the conductive plate; and
forming a second conductive via penetrating through the dielectric layer, the second electrode and the insulating structure.

15. The fabrication method of claim 11, further comprises:
forming a plurality of conductive terminals on the circuit structure.

16. The fabrication method of claim 11, wherein the second electrode comprising:
a plurality of plug portions, disposed in the plurality of trenches; and
a plate portion, connected to the plurality of plug portions.

17. A fabrication method of a semiconductor device, comprising:
providing a semiconductor structure comprising a semiconductor transistor;
forming a front side circuit structure electrically connected to a gate structure of the semiconductor transistor;
forming a backside circuit structure on a side of the semiconductor structure opposite to the front side circuit structure, wherein a method for forming the backside circuit structure comprises:
forming an insulating structure comprising a plurality of trenches;
forming a first electrode, wherein the first electrode comprises:
an extending portion, located on a top surface of the insulating structure;
a plurality of liner portions, disposed in the plurality of trenches and connected to the extending portion, wherein the plurality of liner portions cover the plurality of trenches; and
a plurality of protruding portions, disposed in the plurality of trenches, wherein gaps are laterally located between the plurality of liner portions and the plurality of protruding portions;
forming a dielectric layer on the extending portion, the plurality of liner portions and the plurality of protruding portions; and
forming a second electrode on the dielectric layer, wherein a part of the second electrode is located in the gaps, and the first electrode is separated from second electrode by the dielectric layer.

18. The fabrication method of claim 17, wherein a method for forming the first electrode comprises:
forming a first conductive layer on a top surface of the insulating structure, wherein the first conductive layer covers bottom surfaces and sidewalls of the plurality of trenches;
forming a spacer layer on the first conductive layer in the plurality of trenches, wherein the spacer layer comprises a plurality of openings located in the plurality of trenches;
depositing a conductive material in the plurality of openings on the first conductive layer to form a second conductive layer;
removing a part of the second conductive layer beyond the spacer layer to expose the spacer layer;
removing the spacer layer; and
patterning the second conductive layer.

19. The fabrication method of claim 17, wherein the method for forming the circuit structure further comprises:
forming a conductive plate;
forming the insulating structure above the conductive plate, wherein the plurality of trenches expose a top surface of the conductive plate; and
forming the first electrode in the plurality of trenches, wherein the first electrode is connected to the top surface of the conductive plate.

20. The fabrication method of claim 17, wherein the second electrode comprising:
a plurality of plug portions, disposed in the plurality of trenches, wherein each of the plurality of plug portions surrounds a corresponding one of the plurality of protruding portions; and
a plate portion, connected to the plurality of plug portions.
